(19) United States
(12) Patent Application Publication
(10) Pub. No.: US 2014/0051199 A1
(43) Pub. Date: Feb. 20, 2014

(54) METHOD FOR PRODUCING SILICON SOLOR CELLS HAVING A FRONT-SIDED TEXTURE AND A SMOOTH REAR SIDE

(71) Applicants: Adolf Muenzer, Unterschleißheim (DE); Andreas Teppe, Konstanz (DE); Jan Schoene, Hamburg (DE); Mathias Hein, Hamburg (DE); Jens Kruemberg, Konstanz (DE); Sandra Kruemberg, Konstanz (DE)

(72) Inventors: Adolf Muenzer, Unterschleißheim (DE); Andreas Teppe, Konstanz (DE); Jan Schoene, Hamburg (DE); Mathias Hein, Hamburg (DE); Jens Kruemberg, Konstanz (DE); Sandra Kruemberg, Konstanz (DE)

(21) Appl. No.: 13/993,757

(22) PCT Filed: Dec. 9, 2011
(86) PCT No.: PCT/DE2011/075306

§ 371 Date: Oct. 8, 2013

(30) Foreign Application Priority Data
Dec. 13, 2010 (DE) 10 2010 054 370.5

(51) Int. Cl. H01L 31/0236

(52) U.S. Cl. CPC H01L 31/0236
USPC 438/57

(57) ABSTRACT

Method for producing a silicon solar cell which is smoothly etched on one side, in which a front side and a rear side of a silicon substrate are etched (10) to form a smooth texture, a dielectric coating is then formed (14, 16) on the rear side of the silicon substrate and the front side of the silicon substrate is subsequently textured (20) by means of a texture etching medium, the dielectric coating formed on the rear side of the silicon substrate being used as an etching mask against the texture etching medium.

The invention concerns a method for producing a silicon solar cell which is etched smooth on one side.

In the field of photovoltaics, every effort is made to reduce the expense required to generate current. This can be achieved in the first instance by increasing the efficiency of the manufactured solar cells, or secondly by reducing the expense required to produce solar cells. An improvement in efficiency requires that a greater proportion of the absorbed photons generate electron-hole pairs and/or a greater proportion of the electron-hole pairs generated are conducted away before they can recombine. This improves what is known as the quantum yield or quantum efficiency.

To this end, the surface of a silicon solar cell, or the silicon substrate used to produce the silicon solar cell, can be given a texture using methods known in the art. Such a texture can for example consist of pyramids randomly oriented on the surface. These have the effect of producing multiple reflections of some of the incident light on the pyramid surfaces, which brings about an increased light injection in the silicon solar cell compared with a smooth surface and thereby improves the quantum yield. Furthermore, refraction effects result in an augmented near-surface path of the injected light in the silicon solar cell. Light components which follow such a path can be absorbed closer to the electrical field of a p-n junction formed in the silicon solar cell and as a result are more likely to contribute to the current generated.

Also, light passing into the volume of the silicon solar cell at an angle may cover a longer distance before it strikes the boundaries of the silicon solar cell. Because of the comparatively greater absorption lengths of the long-wave, red light components of the incident light, this is especially advantageous in the red spectral range. Since ever-thinner solar cell substrates are being used in industrial solar cell production, the red spectral range is gaining in importance. Therefore, in order to improve the quantum yield, a metal layer is applied to the rear side of the silicon substrate, thus onto the side of the silicon substrate facing away from the incident light, as optical reflector. As a result, long-wave light striking a front side of the silicon substrate can be reflected to the rear side of the silicon substrate. This increases the probability of absorption of long-wave light in the volume of the silicon substrate and hence the probability of an electron-hole pair being generated. Without optical reflectors on the rear side of the silicon substrate, however, a greater proportion of the light would pass through the silicon substrate without being absorbed.

It has, however, been shown that metallic optical reflectors are associated with a higher charge carrier recombination rate at the boundary of the metal with the silicon substrate. This can be circumvented if, instead of metallic rear side reflectors, a dielectric reflector is provided for the rear side of the silicon substrate. To this end, a dielectric coating is formed on the rear side of the silicon substrate. This can consist of one or more dielectric layers. The dielectric coating is formed in such a way that as many as possible of the photons striking the dielectric coating are reflected through the total reflection effect. This effect replaces the reflection of the photons to the optically denser medium which occurs with metallic rear side reflectors.

With dielectric coatings of this type, which serve as dielectric rear side reflectors, the recombination rate of the charge carrier at the rear side of a silicon solar cell can be significantly reduced. Recombination rates of less than 500 cm/s can be achieved. A full-area rear side aluminium back contact with a back field, which has until now been standard (often referred to as a back surface field), however, only achieves recombination rates in the order of 1000 cm/s. An ohmic metallic back contact without back field used as rear side reflector even has recombination rates of over 10⁶ cm/s.

As already explained, the reflective effect of the dielectric coating relies on the effect of the total reflection of light to the dielectric coating. This only starts, however, when the light strikes the boundary between silicon substrate and dielectric layer at angles which meet the conditions for total reflection. The meeting of this condition is enhanced by an oblique light injection into the silicon substrate. As explained above, oblique light injection can be realised by a texture on the front side of the silicon substrate for part of the incident light. In order to meet the condition for a total reflection to the rear side for the greatest possible part of the light injected into the silicon solar cell, a rear side surface of the silicon substrate which is as smooth as possible is the most suitable. A high quantum yield can therefore be realised by a texture on the front side of the silicon substrate in combination with a rear surface of the silicon substrate which is as smooth as possible.

In industrial solar cell production textures are usually formed wet-chemically using appropriate texture etching solutions. Also, the smoothing or polishing of surfaces of the silicon substrate on an industrial scale is done wet-chemically. As a rule, this involves immersing the silicon substrate in suitable etching solutions. As a result, textures are usually formed on both the front side and the rear side. Accordingly, smoothing of the surface is usually carried out on both the front side and on the rear side. The formation of a one-sided polish or one-sided smoothing of the surface of the silicon substrate, however, has always previously been associated with a considerable additional production cost, which substantially narrows, if not completely overcompensates for, the advantage of an improved quantum yield.

Against this background, the present invention is based on the problem of making available an economical method for the production of silicon solar cells with a front texture and smooth rear side surface.

This problem is solved by a method with the features of claim 1. Advantageous refinements are the subject matter of dependent sub-claims.

The method according to the invention for the production of a silicon solar cell which is smooth on one side provides that a front side and a rear side of a silicon substrate are etched smooth, a dielectric coating is subsequently formed on the rear side of the silicon substrate and the front side of the silicon substrate is then textured by means of a texture etching medium, the dielectric. coating formed on the rear side of the silicon substrate serving as an etching mask against the texture etching medium.

A front side of the silicon substrate in this instance means that side of the silicon substrate which, in the solar cell produced from the silicon substrate, faces towards the incident light. Correspondingly, the rear side of the silicon substrate means that side which in the finished solar cell faces away from the incident light. Smooth etching within the meaning of the present invention means etching by means of which the surface of the silicon substrate is smoothed in such a way that at least 15% of incident light with a wavelength of between 400 nm and 1000 nm is reflected. Polish etching in the present sense represents a special kind of smooth etching, in which the surface of the silicon substrate is smoothed in such a way that at least 25% of incident light with a wavelength of between 400 nm and 1000 nm is reflected.

The dielectric coating in the present sense is used as etch masking, when the dielectric coating of the texture etching medium is not etched to a significant extent within the limit of the etching times required for the texturing of the front side. Ideally, the etch masking, i.e. the dielectric coating, would be chemically inert with respect to the texture etching medium. This is, however, not absolutely necessary. In principle, it is sufficient to select the thickness of the dielectric coating and its density in such a way that the dielectric coating is not removed to a significant extent, so that the rear side of the silicon substrate is protected by the dielectric coating from the texture etching medium and the dielectric coating is left on the silicon substrate in a desired thickness.

Since the dielectric coating used as etch masking is used in the finished solar cell as optical rear side reflector, it can be left on the silicon substrate. Compared with other etch maskings, this offers the advantage that the etch masking need not be removed after texturing the front side and the silicon substrate can nevertheless be completely immersed in the texture etching medium. This enables economical one-sided texturing of the silicon substrate on its front side. Since the front side and the rear side of the silicon substrate are etched smooth, compared with a solar cell textured on the rear and provided on the rear side with a dielectric coating as optical rear side reflector, this offers the advantage that the dielectric coating has a more homogeneous thickness, due to the smoother rear side surface of the silicon substrate, which has an advantageous effect on both the optical and the electrical properties of the dielectric coating. Furthermore a thicker dielectric coating can be formed with the same quantity of dielectric coating material, or, with comparable thickness, the quantity of dielectric coating material used can be reduced. This is because a textured rear side has a larger surface area (by a factor of about 1.7) than a smooth rear side, and therefore the quantity of dielectric coating material used for a textured rear side has to be distributed over a larger surface area. As a side effect, increased breaking strength of the silicon substrate may also be effected, due to its smooth rear side surface.

The smooth etching of the front and rear side of the silicon substrate can take place simultaneously in a joint etching step.

Advantageously, saw damage or other surface defects of the silicon substrate can be etched and thereby removed as part of the smooth etching process.

Monocrystalline silicon substrates can be used as silicon substrates, and the invention has proven especially successful with these.

Preferably, the rear side of the silicon substrate is electrically passivated by means of the dielectric coating. This reduces the surface recombination rate of the charge carrier on the rear side of the silicon substrate. The smooth rear side surface of the silicon substrate compared with a structured or textured rear side surface achieves an improved passivation effect, since no inhomogeneities occur at the peaks of textures or structures.

Preferably a stack of dielectric layers is formed as dielectric coating. It has proven to be advantageous to this end firstly to form a silicon oxide layer on the rear side of the silicon substrate and subsequently to form a silicon nitride layer on the silicon oxide layer. In this case the silicon oxide layer is preferably formed in a thickness of less than 100 nm and the silicon nitride layer preferably in a thickness of less than 200 nm. The silicon oxide layer can be formed by means of thermal oxidation of the silicon substrate or applied to the silicon substrate using plasma-enhanced chemical deposition from the vapour phase. The silicon nitride layer is preferably formed by means of a plasma-enhanced chemical deposition from the vapour phase (PECVD).

If a stack of dielectric layers consisting of a silicon oxide layer formed on the rear side of the silicon substrate and a silicon nitride layer subsequently formed on the silicon oxide layer is used, in practice it has proven successful to form silicon oxide layers in a thickness between 5 nm and 100 nm, preferably between 10 nm and 50 nm. In this connection it has also proven successful to form silicon nitride layers in a thickness between 50 nm and 200 nm, preferably between 70 nm and 150 nm.

Advantageously the dielectric coating is kept at temperatures of at least 700° C. for a period of at least 5 minutes, before a metallic medium is applied to the dielectric coating. In this way, the dielectric coating can be condensed and hence its resistance to etching media or a fire-through of metallic pastes through the dielectric coating can be increased.

Preferably, the front side and the rear side of the silicon substrate are smooth etched in an alkaline etching solution. In this connection aqueous NaOH or KOH solutions with an NaOH or KOH concentration of 10 to 50 percent by weight, especially preferably of 15 to 30 percent by weight, have proven successful. The use of such etching solutions is economical. Also, they allow smooth etching of silicon substrates in large numbers and can thus be used in industrial mass-production. Furthermore, by using etching solutions which have the said NaOH or KOH concentrations, reflections over 35% in the wavelength range between 400 nm and 1000 nm can be realised, so that they enable polish etching.

It is preferable to use an alkaline texture etching medium as texture etching solution, preferably one containing NaOH or KOH. As already mentioned above, such texture etching solutions allow the process to be carried out economically and are also well-suited to industrial mass-production.

Advantageously, before forming the dielectric coating, a surface of the silicon substrate is cleaned, at least on its rear side.

This can improve the electric passivation effect of the dielectric coating. Preferably, this is done by using an HF containing solution into which gaseous ozone is fed. This enables economical cleaning. Alternatively, known cleaning sequences, for example “IMEC cleaning” or a cleaning sequence which has become known by the term “RCA cleaning” can be used. These are, however, linked with additional expense. A cheaper alternative to these cleaning sequences consists of using a solution containing HCl and HF. In practice, it has proven successful to dip the silicon substrate in the solution being used in order to clean the rear side.

After forming the dielectric coating, it is preferable to over-etch at least the front side of the silicon substrate using an HF solution to remove any dielectrics deposited on the front side of the silicon substrate when forming the dielectric coating. This method can prevent or at least reduce any impairment of the texture due to parasitic dielectrics on the front side of the silicon substrate. In one economical variant embodiment the silicon substrate is dipped into the HF solution. In this case, the HF solution also comes into contact with the dielectric coating formed on the rear side of the silicon substrate. The HF-concentration of the HF solution and the etching time are advantageously selected in this case such that the dielectric coating is only slightly etched. In practice, aqueous HF solutions with an HF concentration of less than 5 percent by weight, preferably of less than 2 and especially preferably of less than 1 percent by weight, have proven successful as HF solutions for over-etching the front side of the silicon substrate.

Preferably after texturing the front side of the silicon substrate, an emitter is formed on the front side of the silicon substrate, by diffusing dopant into the front side of the silicon substrate. Since, during this diffusion step, the dielectric coating has already been formed on the rear side of the silicon substrate, this can be used as a diffusion barrier during the diffusion process. This enables an economical realisation of a one-sided emitter diffusion regardless of the type of diffusion technology used. So, for example, the diffusion can be realised in stack operation by means of a POCl₃ diffusion or in a continuous diffusion furnace using diffusion sources applied to the front side of the silicon substrate (known as precursor diffusion). Therefore edge insulation can be omitted.

Preferably the silicon substrate is cleaned with an etching solution before the dopant is diffused in. In this connection, cleaning with an etching solution containing HF ad HCl has proven successful. The composition of the etching solution and etching parameters such as the etching time should be selected such that the dielectric coating on the rear side of the silicon substrate is not significantly etched. In practice etching solutions containing HF and HCl with an HF concentration of less than 5 percent by weight, preferably of less than 2 and preferably of less than 1 percent by weight have proven successful.

As explained above, a texture etching solution containing NaOH or KOH can be used as texture etching medium. As it has emerged, however, it may happen that such texture etching solutions, which usually contain isopropyl alcohol, do not attack a smooth or polish etched silicon surface locally, or there is a delay. This can lead to inhomogeneities in the texture. One refinement of the invention therefore provides that a texture etching solution is used as texture etching medium which contains NaOH and KOH as well as a product which is obtainable by mixing at least one polyethylene glycol with a base to form a single-phase mixture, heating the single-phase mixture to a temperature of 80° C. and allowing the single-phase mixture to rest in ambient air until the single-phase mixture changes colour. In this context, base means in principle any compound and any element which is capable of forming hydroxide ions in aqueous solution. It is preferable to use an alkali hydroxide or an ammonium hydroxide as base, especially preferably potassium or sodium hydroxide. The proportion by mass of the alkali hydroxide used to the components mixed to form the single-phase mixture, for example tetraethylene glycol and potassium hydroxide, is 1 to 10 percent by mass, preferably about 7 percent by mass.

A single-phase mixture in this context means that the mixture, even if left to stand for a longer period of several hours, does not separate into several phases of varying density. Ambient air in the present sense is a gas mixture usually present on earth in areas occupied by humans. The term of “allowing to rest” does not necessarily mean absolute rest of the mixture. In principle the mixture can also be moved. A change of colour of the single-phase mixture exists when the single-phase mixture changes its colour compared to its original colour. In particular, a change of colour has occurred when a previously transparent single-phase mixture takes on a colour. The resting period until change of colour depends on many parameters, in particular the substances mixed. In most cases, a rest for a period from about 15 minutes to 16 hours is required.

The refinement described makes it possible to form a complete and uniform texture on the smooth etched front side surface of the silicon substrate.

One variant of the refinement described provides that the product contained in the texture etching solution can be obtained by mixing at least one polyethylene glycol with a base and water to form a single-phase mixture, heating the single-phase mixture to a temperature of 80° C. and allowing the single-phase mixture to rest in ambient air until the single-phase mixture changes colour. Preferably, in this case, in the manufacture of the product, an aqueous alkali hydroxide solution is mixed with the at least one polyethylene glycol.

In a further variant of the refinement described, as the product contained in the texture etching solution, a product is used which can be obtained by mixing at least one polyethylene glycol with a base to form a single-phase mixture, heating the single-phase mixture to a temperature of 80° C., allowing the single-phase mixture to rest in ambient air until the single-phase mixture changes colour and admixing a non-oxidising acid into the single-phase mixture after it has changed colour. This non-oxidising acid is preferably hydrochloric acid or acetic acid. It has proven to be advantageous to admix the non-oxidising acid in such a way that a pH value of less than 7, preferably of less than 3, ensues. The use of such a product can counteract premature deterioration of the etching effect of the texture etching solution.

In the variants of the refinement described, it is preferable always to use a product which has been allowed to rest until the single-phase mixture takes on a colour which lies in the optical colour spectrum between orange and red-brown, especially preferably until it takes on a red-brown colour.

The method according to the invention allows the use of economical alkaline etching and texture etching solutions. It also allows the amount of silicon etched from the silicon substrate to be minimised and hence also reduces the consumption of etching media, which both have an advantageous effect on the cost of manufacture of a solar cell.

The method according to the invention is also compatible with modern solar cell manufacturing processes. So for example laser diffusion steps to form a selective emitter structure or steps for local opening of the dielectric coating on the rear side of the silicon substrate by means of laser or etching paste can easily be integrated. Proven manufacturing steps such as the formation of an antireflection coating and simultaneous passivation of the silicon substrate volume by means of hydrogen by applying a silicon nitride layer can easily be combined with the invention.

The table below shows the solar cell parameters of two silicon solar cells:

| | | Short- | | |
|---|---|---|---|---|
| | | circuit | No-load | |
| | | current | voltage | Fill |
| | Efficiency % | mA/cm³ | mV | factor % |
| Rear | 18.75 | 37.8 | 637 | 77.9 |
| side | | | | |
| smooth: | | | | |
| Rear | 16.13 | 35.2 | 604 | 75.9 |
| side | | | | |
| textured: | | | | |

These differ in that a silicon solar cell has been produced in accordance with the method according to the invention and has a dielectric coating which has been formed on a smooth rear side. In the second silicon solar cell, however, the dielectric coating has been formed on a textured rear side. As can be seen from the values for short-circuit current and no-load voltage, in the case of the solar cell with a smooth rear side the improved light reflection to the solar cell rear side and the dielectric passivation of the rear side can be profitably used while the solar cell with textured rear side exhibits values which only vary slightly from those of solar cells without dielectric rear side passivation.

Next, the invention will be explained in more detail with the aid of a figure, which shows:

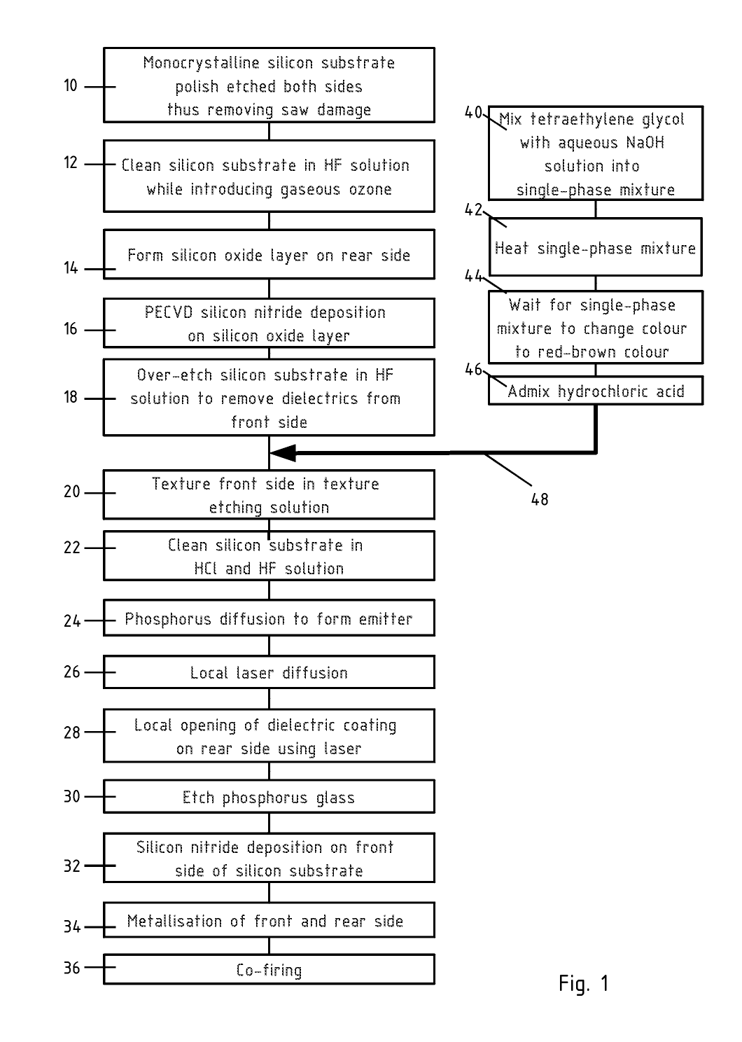

FIG. 1 Schematic view of an embodiment of the method according to the invention.

FIG. 1 shows in schematic view an embodiment of the method according to the invention. In this a monocrystalline silicon substrate is polish-etched 10 on both sides, i.e. front and rear side. In the present embodiment this is done in a KOH solution with a KOH concentration of 25 percent by weight. As explained above, polish etching represents a special kind of smooth etching. For practical purposes any saw damage on the silicon substrate is thereby etched and thus removed 10.

The silicon substrate is subsequently cleaned 12 in an HF solution into which gaseous ozone is fed. As already explained, this represents an economical cleaning option. In principle, however, other cleaning sequences of prior art can also be used. As described above, this cleaning step 12 can improve the electrical passivation effect of a subsequently formed dielectric coating.

For the purposes of forming a dielectric coating, a silicon oxide layer is next formed 14 on the rear side of the silicon substrate. This can be done by means of thermal oxidation of the rear side surface of the silicon substrate or by deposition of silicon oxide on the rear side of the silicon substrate. In the latter case, it is preferable to use plasma-enhanced chemical deposition from the vapour phase (PECVD). PECVD is then used to deposit 16 a silicon nitride layer on the silicon oxide layer. This silicon nitride layer, together with the silicon oxide layer already formed 14, forms the dielectric coating.

In the present embodiment, the silicon substrate is then over-etched 18 in an HF solution, in order to remove any parasitic dielectrics deposited on the front side of the silicon substrate. The over-etching 18 is realised here by means of a brief immersion of the silicon substrate in the HF solution, which is sometimes referred to as an “HF dip”. The HF concentration of the HF solution and the etching time are selected such that the dielectric coating formed on the rear side of the silicon substrate is only slightly etched, so that its function is not affected.

The front side of the silicon substrate is next textured 20 using a texture etching solution. In the present embodiment, this involves the silicon substrate being dipped into the texture etching solution. The dielectric coating formed 14, 16 on the rear side of the silicon substrate is now used as etch masking against the texture etching solution, so that no texture is formed on the rear side of the silicon substrate.

In order that the front side of the silicon substrate can be textured 20 in the texture etching solution, the texture etching solution required for this is prepared 48 in advance. In the present embodiment, this is done by preparing 48 a texture etching solution containing NaOH, which also contains a product obtainable, as indicated schematically in FIG. 1, by mixing 40 tetraethylene glycol with an aqueous NaOH solution to form a single-phase mixture, heating 42 the single-phase mixture to a temperature of 80° C., allowing the single-phase mixture to rest in ambient air, i.e. waiting 44 until the single-phase mixture changes colour to a red-brown colour and subsequently admixing 46 hydrochloric acid into the single-phase mixture.

After texturing 20 the front side of the silicon substrate in the texture etching solution, the silicon substrate is cleaned 22 in a solution containing HCl and HF. The etching parameters are selected for this in such a way that the dielectric coating on the rear side of the silicon substrate is not etched to any significant extent. This is followed by a phosphorus diffusion 24 in order to form an emitter on the front side of the silicon substrate. During the phosphorus diffusion 24, the dielectric coating on the rear side of the silicon substrate serves as a diffusion barrier, so that no phosphorus can diffuse into the rear side of the silicon substrate.

After this, an optional, local laser diffusion 26 can take place on the front side of the silicon substrate. In this case, for example, the silicon substrate can be locally heated in such a way that diffusion into the silicon substrate of phosphorus from a phosphorus glass formed 24 during the phosphorus diffusion is locally enhanced. In particular, selective emitter structures can be formed in this way.

The dielectric coating on the rear side of the silicon substrate is then opened 28 locally using a laser, or its laser radiation. The rear side of the silicon substrate can then be contacted via these local openings by means of a metallisation applied to the dielectric coating.

This is followed by etching 30 of the phosphorus glass. A silicon nitride containing hydrogen is then deposited 32 on the front side of the silicon substrate, which serves as antireflection coating of the solar cell and whose hydrogen content enables a defect passivation in the volume of the silicon substrate.

In the further course of the process, the front and the rear side of the silicon are metallised 34 in a way known in the art, for example by means of known printing methods such as screen printing, and the metallisations on the front and rear side are then co-fired 36, in order to produce the electrical front and rear side contacts of the solar cell.

1. A method for producing a silicon solar cell which is smoothly etched on one side, comprising:
smooth etching of a front side and a rear side of a silicon substrate
forming a dielectric coating on the rear side of the silicon substrate; and
texturing the front side of the silicon substrate by means of a texture etching medium, the dielectric coating formed on the rear side of the silicon substrate being used as etching mask against the texture etching medium.

2. The method according to claim 1, characterised in that the rear side of the silicon substrate is electrically passivated by means of a dielectric coating.

3. The method according to claim 2, characterised in that a stack of dielectric layers is formed as the dielectric coating.

4. The method according to claim 3, characterised in that for the purpose of forming the dielectric coating, firstly a silicon oxide layer is formed on the rear side of the silicon substrate and subsequently a silicon nitride layer is formed on the silicon oxide layer, the silicon oxide layer preferably being formed in a thickness of less than 100 nm and the silicon nitride layer in a thickness of less than 200 nm.

5. The method according to claim 3, characterised in that the dielectric coating is formed whose thickness has a value of between 100 nm and 200 nm.

6. The method according to claim 1, characterised in that the front side and the rear side of the silicon substrate are etched smooth in an alkaline etching solution, preferably in an aqueous NaOH or KOH solution with an NaOH or KOH concentration of 10 to 50 percent by weight and especially preferably in an aqueous NaOH or KOH solution with an NaOH or KOH concentration of 15 to 30 percent by weight.

7. The method according to claim 1, characterised in that an alkaline texture etching solution is used as texture etching medium, preferably a texture etching solution containing NaOH or KOH.

8. The method according to claim 1, characterised in that before formation of the dielectric coating, one or more of the front and rear sides of the silicon substrate is cleaned, at least on its rear side, preferably by means of an HF solution into which gaseous ozone is introduced.

9. The method according to claim 1, characterised in that after formation of the dielectric coating at least the front side of the silicon substrate is over-etched by means of an HF containing solution to remove any dielectrics deposited on the front side of the silicon substrate when forming the dielectric coating.

10. The method according to claim 1, characterised in that after texturing the front side of the silicon substrate by diffusion of dopant into the front side of the silicon substrate an emitter is formed.

11. The method according to claim 10, characterised in that before the dopant is diffused in, the silicon substrate is cleaned using an etching solution, preferably using an etching solution containing HF and HCl.

12. The method according to claim 1, characterised in that a texture etching solution is used as the texture etching medium which contains one element from the group consisting of NaOH and KOH and also a product which is obtainable by
mixing at least one polyethylene glycol with a base to form a single-phase mixture;
heating the single-phase mixture to a temperature of 80° C.; and
allowing the single-phase mixture to rest in ambient air until the single-phase mixture changes colour.

13. The method according to claim 1, characterised in that a texture etching solution is used as the texture etching medium, which contains an element from the group consisting of NaOH and KOH and also a product which is obtainable by
mixing at least one polyethylene glycol with a base and water to form a single-phase mixture;
heating the single-phase mixture to a temperature of 80° C. and
allowing the single-phase mixture to rest in ambient air until the single-phase mixture changes colour.

14. The method according to claim 1, characterised in that a texture etching solution is used as the texture etching medium which contains an element from the group consisting of NaOH and KOH and also a product which is obtainable by
mixing at least one polyethylene glycol with an element from a group consisting of NaOH and KOH to form a single-phase mixture;
heating the single-phase mixture to a temperature of 80° C.; and
allowing the single-phase mixture to rest in ambient air until the single-phase mixture changes colour.

15. The method according to claim 1, characterised in that a texture etching solution is used as the texture etching medium which contains an element from the group consisting of NaOH and KOH and also a product which is obtainable by
mixing at least one polyethylene glycol with a base to form a single-phase mixture;
heating the single-phase mixture to a temperature of 80° C. and
allowing the single-phase mixture to rest in ambient air until the single-phase mixture changes colour; and
admixing a non-oxidising acid, preferably hydrochloric acid or acetic acid, into the single-phase mixture after it has changed colour.
